(19) United States
(12) Patent Application Publication
(10) Pub. No.: US 2026/0074138 A1
(43) Pub. Date: Mar. 12, 2026

(54) ION SOURCE AND OPERATING METHOD THEREOF

(71) Applicant: NISSIN ION EQUIPMENT CO., LTD., Koka-city (JP)

(72) Inventor: Hiroaki KAI, Koka-city (JP)

(21) Appl. No.: 19/319,649

(22) Filed: Sep. 4, 2025

(30) Foreign Application Priority Data
Sep. 12, 2024 (JP) 2024-158557

(51) Int. Cl. H01J 37/08; H01J 37/24; H01J 37/317

(52) U.S. Cl. CPC H01J 37/08; H01J 37/241; H01J 37/3171; H01J 2237/061; H01J 2237/082

(57) ABSTRACT

An ion source is provided which can operate in a monomer mode or a cluster mode without experiencing losses. According to embodiments, an ion source can include a cathode that emits electrons. A plasma generation chamber can have an opening region through which the electrons pass. An electrode can be disposed between the cathode and the opening region, the electrode including a cylindrical portion through which the electrons pass. The electrode can be set to a negative potential with respect to the plasma generation chamber or a positive potential with respect to the plasma generation chamber. An exemplary method can include setting the electrode to a negative potential with respect to the plasma generation chamber if the ion species is a monoatomic ion, or setting the electrode to a positive potential with respect to the plasma generation chamber if the ion species is a molecular ion.

### CROSS-REFERENCE TO RELATED APPLICATION

This application claims priority from Japanese Patent Application No. JP 2024-158557, filed in the Japanese Patent Office on Sep. 12, 2024, the disclosure of which being incorporated by reference herein in its entirety.

### BACKGROUND

### 1. Field

The present disclosure relates to an ion source which is incorporated into an ion implantation apparatus and a method for operating the ion source and ion implantation apparatus.

### 2. Description of Related Art

Ion sources used in ion implanters typically operate in a monomer mode or a cluster mode. An ion source operates in a monomer mode when the ions implanted into the target are monatomic ions. An ion source can also be configured to operate in a cluster mode which occurs when the ions implanted into the target are molecular ions.

A typical ion source includes an ionization chamber in which plasma is generated, and an electron gun that supplies electrons to the ionization chamber. The electron gun emits electrons by heating a cathode.

The electron gun includes a cathode that emits thermal electrons upon being heated, an anode that is maintained at a positive potential with respect to the cathode by an anode power supply, the anode attracting and accelerating the electrons, and a controller that controls power supply to the anode. The ion source can generate plasma that can be emitted by the electron gun when the controller applies a positive voltage to the anode.

If the controller shuts off the power supply to the anode, setting the voltage to the anode to zero, the plasma is extinguished. The controller can also switch the ion source from a monomer mode to a cluster mode by changing the voltage applied to the anode.

### SUMMARY

According to an aspect of one or more embodiments of the disclosed subject matter, an ion source for generating an ion beam containing a predetermined ion species can be provided. The ion source can include a cathode that emits electrons, a plasma generation chamber having an opening region through which the electrons pass, and in which plasma containing the ion species is generated from a source gas, and an electrode disposed between the cathode and the opening region, the electrode including a cylindrical portion through which the electrons pass. The electrode can be configured to be set to a negative potential with respect to the plasma generation chamber or a positive potential with respect to the plasma generation chamber.

According to another aspect of one or more embodiments, a method for operating an ion source is disclosed. The ion source generates an ion beam containing a predetermined ion species, and can include a cathode that emits electrons, a plasma generation chamber having an opening region and an electrode disposed between the cathode and the opening region, where the electrode including a tubular portion. The method can include passing electrons through the opening region of the plasma generation chamber in which plasma containing the ion species is generated from a source gas, passing electrons through the tubular portion of the electrode, and selecting whether to set the electrode to a positive potential with respect to the plasma generation chamber or to set the electrode to a negative potential with respect to the plasma generation chamber, depending on the ion species.

According to another aspect of one or more embodiments, a method for operating an ion source that generates an ion beam containing a predetermined ion species is disclosed. The method can include providing a cathode that emits electrons, a plasma generation chamber having an opening region and an electrode disposed between the cathode and the opening region, passing electrons through the opening region of the plasma generation chamber in which plasma containing the ion species is generated from a source gas; passing electrons through the electrode, and setting the electrode to a negative potential with respect to the plasma generation chamber if the ion species is a monoatomic ion.

It is an aspect of certain embodiments to improve extraction efficiency of an ion beam according to a desired ion species.

### BRIEF DESCRIPTION OF DRAWINGS

FIG. 1 is a schematic diagram of an embodiment of an ion source made in accordance with principles of the presently disclosed subject matter.

FIG. 2 is a schematic diagram showing a cross-sectional view of the periphery of a cathode and a circuit configuration of an ion source according to the embodiment shown in FIG. 1.

FIG. 3 is a schematic diagram showing a cross-sectional view of the periphery of a cathode and a circuit configuration of an ion source in accordance with another embodiment of the disclosed subject matter.

FIG. 4 is a schematic diagram showing a cross-sectional view of the periphery of a cathode and a circuit configuration of an ion source in accordance with another embodiment of the disclosed subject matter.

FIG. 5 is a diagram showing the relationship between the potential of the bias electrodes with respect to the plasma generation chamber and the beam current values based on the results of a test in which an ion beam of monoatomic ions (H⁺) was extracted from H₂ gas.

FIG. 6 is a diagram showing a relationship between a potential of a bias electrode with respect to a plasma generation chamber and a beam current value based on results of a test extracting ion beams of various monoatomic ions (B⁺, Si⁺, C⁺, and P⁺) from various source gases.

FIG. 7 is a diagram showing the relationship between the potentials of the bias electrodes with respect to the plasma generation chamber and the beam current values based on results of tests of extracting ion beams of various molecular ions (BF₂⁺, CO₂⁺ gas, and P₂⁺) from various source gases.

### DETAILED DESCRIPTION

In a conventional ion source having a monomer mode and a cluster mode, when the ion source operates in the monomer mode, a part of the electrons emitted from an electron gun flows from an anode to an anode power supply, thereby reducing the electron transport efficiency. This reduces the efficiency of ionizing the source gas, and reduces the extraction efficiency of the ion beam.

Furthermore, if the anode is eliminated, the ion source cannot operate in cluster mode, and thus the extraction efficiency of the ion beam for extracting the molecular ions is reduced.

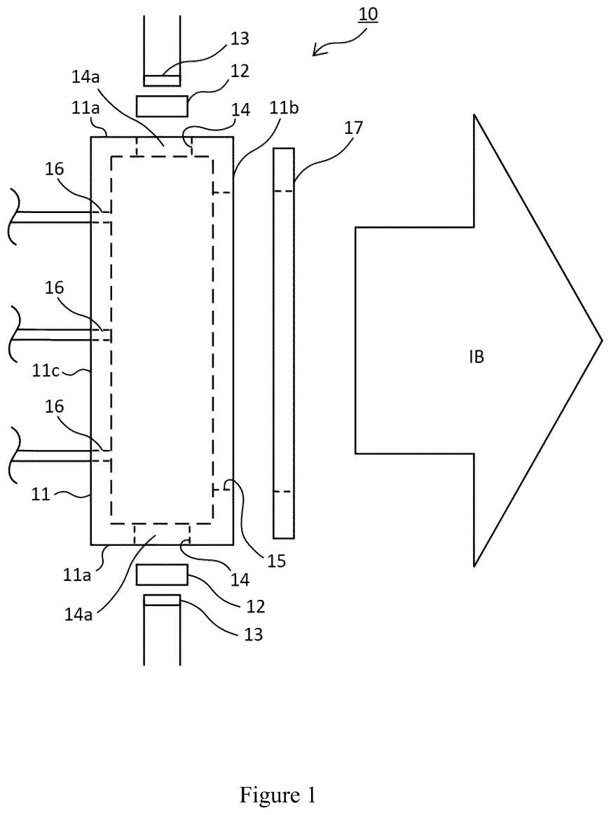

FIG. 1 is a schematic diagram of an embodiment of an ion source 10 made in accordance with principles of the presently disclosed subject matter.

The ion source 10 of this embodiment can be incorporated into an ion implantation apparatus used in a semiconductor manufacturing process, for example. As shown in FIG. 1, the ion source 10 generates an ion beam IB containing a predetermined ion species.

The predetermined ion species is an ion species that is selected for a particular process in which the ion source 10 is used. The ion source is selected and can be changed depending upon the target (not shown) to be irradiated with the ion beam IB or depending upon the purpose of irradiation with the ion beam IB.

The ion source 10 can include a plasma generation chamber 11 in which plasma is generated. The plasma generation chamber 11 of this embodiment has a substantially rectangular parallelepiped shape. The plasma generation chamber 11 can have a pair of bottom walls 11a facing each other in the longitudinal direction of the plasma generation chamber 11.

An opening 14 penetrating through the bottom 11a can be formed in each bottom wall 11a. The opening 14 forms an opening region 14a through which electrons supplied from the cathode 12 can flow. Thus, the plasma generation chamber 11 has an opening region 14a through which electrons supplied from the cathode 12 pass.

The ion source 10 includes a cathode 12 that emits electrons toward the plasma generation chamber 11. The cathode 12 can be an indirectly heated cathode. The ion source 10 also can include a filament 13 that emits electrons causing the cathode 12 to heat up.

In this embodiment, the cathodes 12 are disposed outside the respective openings 14. Thus, the ion source 10 of this embodiment includes two cathodes 12 and two filaments 13. The ion source 10 may have a configuration in which the opening 14 is formed only in one of the pair of bottom walls 11 and having only one cathode 12 and one filament 13.

The plasma generation chamber 11 can have an extraction opening 15 for extracting the ion beam IB. The extraction opening 15 is formed in a first sidewall 11b which is one sidewall connecting two bottom walls 11a. The plasma generation chamber 11 has a plurality of gas introduction openings 16 for supplying a raw material gas into the plasma generation chamber 11. Each gas introduction opening 16 is formed in a second sidewall 11c opposite to the first sidewall 11b. In this embodiment, the plasma generation chamber 11 has three gas introduction openings 16, but the number of gas introduction openings 16 is not limited to a specific number.

In the plasma generation chamber 11, plasma containing the selected ion species is generated by the source gas introduced from outside of the chamber 11 through the gas introduction opening 16 and the electrons emitted from the cathode 12. The raw material gas introduced into the plasma generation chamber 11 can be changed or ionized according to the desired ion type.

The ion source 10 can include an extraction electrode 17 for extracting the ion beam IB from the plasma generated in the plasma generation chamber 11. The extraction electrode 17 can be disposed outside the plasma generation chamber 11 and faces the extraction opening 15.

The ion source 10 can extract ions contained in the plasma generated inside the plasma generation chamber 11 from the extraction opening 15 as an ion beam IB. The ion beam IB extracted from the plasma generation chamber 11 is subjected to mass separation, and the ion beam IB containing a selected ion species is applied to a target (not shown). The target is, for example, a semiconductor wafer.

By irradiating the target with the ion beam IB, desired ions are implanted into the target. The purpose of irradiating the target with the ion beam IB may be, for example, surface modification of the target.

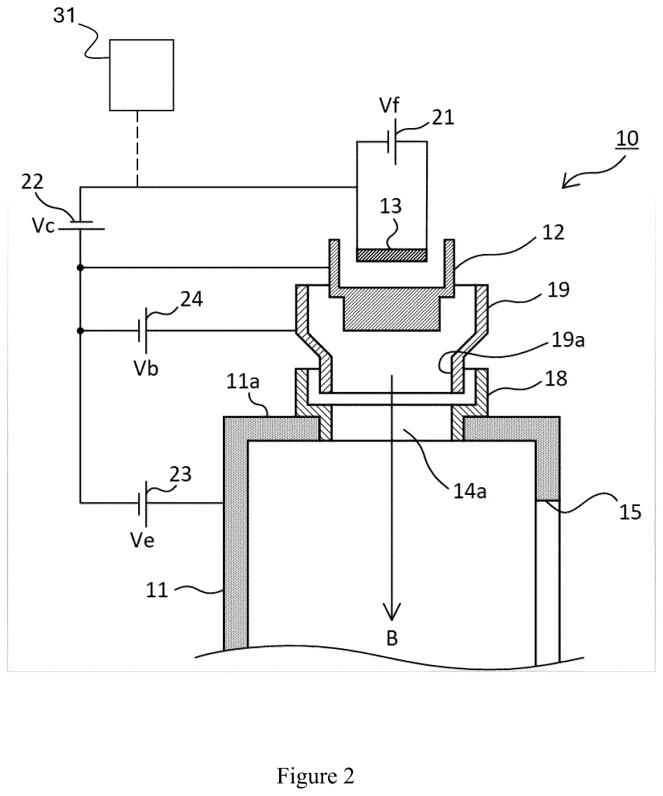

FIG. 2 is a schematic diagram showing a cross section of an exemplary ion source 10 around the cathode 12 and a configuration of an electric circuit of the ion source 10. The ion source 10 of this embodiment includes two cathodes 12, but the cathodes 12 and the configurations around the cathodes 12 can be the same as described above in connection with the embodiment of FIG. 1. Therefore, only one of the cathodes 12 and the structure around the cathode 12 are shown in FIG. 2.

As shown in FIG. 2, the ion source 10 can include a ground element 18 mounted in the opening 14 of the plasma generation chamber 11. The ground element 18 is fixed to the plasma generation chamber 11 and has the same potential as the plasma generation chamber 11. The ground elements 18 can be formed in a cylindrical shape, and even when the ground elements 18 are attached to the opening 14, electrons emitted from the cathode 12 pass through the opening region 14a.

The ion source 10 can further include bias electrodes 19 which are electrodes disposed between the cathode 12 and the opening region 14a of the plasma generation chamber 11. The bias electrodes 19 can have a cylindrical portion 19a through which electrons emitted from the cathode 12 can pass.

The bias electrode 19 can be disposed between the ground element 18 and the cathode 12. An insulator (not shown) can be disposed between the cathode 12 and the ground element 18, and the ground element 18 and the cathode 12 are positioned to be separated by a predetermined interval in the longitudinal direction of the plasma generation chamber 11.

The ion source 10 can include an electromagnet (not shown), and forms a magnetic field B along the longitudinal direction of the plasma generation chamber 11 inside the plasma generation chamber 11. Some of the electrons emitted from the cathode 12 can be supplied to the plasma generating chamber 11 through the inside of the cylindrical portion 19a of the bias electrode 19 and the opening region 14a while being captured by the magnetic field B.

The ion source 10 can include a filament power supply 21 that applies a filament voltage Vf between both ends of the filament 13. The ion source 10 can also include a cathode power supply 22 that is disposed between the cathode 12 and the filament 13 on the circuit and applies a cathode voltage Vc to the cathode 12 to keep the cathode 12 at a positive potential with respect to the filament 13.

The ion source 10 can include an emitter power supply 23 that is disposed between the plasma generation chamber 11 and the cathode 12 on the circuit and applies an emitter voltage Ve to the plasma generation chamber 11 to keep the plasma generation chamber 11 at a positive potential with respect to the cathode 12.

The ion source 10 can also include a bias power supply 24 capable of setting the bias electrode 19 to a negative potential with respect to the plasma generation chamber 11 while keeping the bias electrode 19 at a positive potential with respect to the cathode 12. In this embodiment, the positive side of a bias power supply 24 is electrically connected to the bias electrode 19, and a bias voltage Vb is applied to the plasma generation chamber 11. The negative side of the bias power supply 24 is electrically connected to the negative side of the emitter power supply 23.

Therefore, the ion source 10 can set the bias electrode 19 to a negative potential with respect to the plasma generation chamber 11 by adjusting the value of the bias voltage Vb to be smaller than the value of the emitter voltage Ve, that is, by setting (bias voltage Vb)<(emitter voltage Ve).

In addition, the ion source 10 can set the bias electrode 19 to a positive potential with respect to the plasma generation chamber 11 by adjusting the value of the bias voltage Vb to be larger than the value of the emitter voltage Ve, that is, by setting (bias voltage Vb)>(emitter voltage Ve).

Thus, the ion source 10 can set the bias electrode 19 to either a negative potential or a positive potential with respect to the plasma generation chamber 11 by adjusting the bias voltage Vb applied by the bias power supply 24. In addition, the ion source 10 can also set the bias electrode 19 to the same potential as the plasma generation chamber 11 by adjusting the bias voltage Vb applied by the bias power supply 24.

The configuration in which the bias power supply 24 is connected to the bias electrode 19 and the plasma generation chamber 11 in this embodiment is exemplary.

The ion source 10 may have any configuration as long as the bias electrode 19 can be set to either a negative potential or a positive potential with respect to the plasma generation chamber 11 while the plasma generation chamber 11 is maintained at a positive potential with respect to the cathode 12.

A controller 31 can be provided to control power output by the filament power supply 21, cathode power supply 22, bias power supply 24 and/or emitter power supply 23 in accordance with the principles and methods described herein with respect to the circuit. Further, the controller 31 can be configured to control the bias electrode 19 to be set to either a negative potential or a positive potential with respect to the plasma generation chamber 11 while the plasma generation chamber 11 is maintained at a positive potential with respect to the cathode 12.

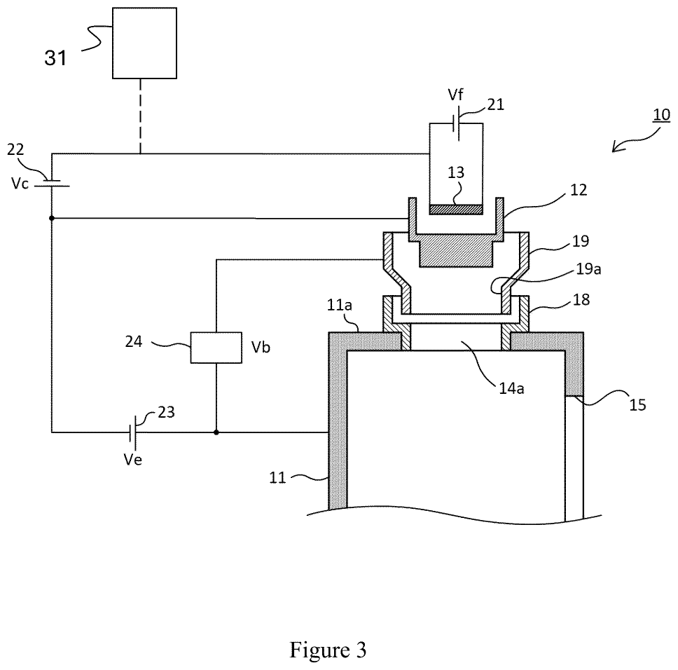

FIG. 3 is a diagram showing a cross section of the periphery of the cathode 12 according to a first modification of the ion source 10 and a circuit configuration of the ion source 10. In FIG. 3, only one cathode 12 and the structure around the cathode 12 are shown, as in FIG. 2.

In the first modification, the bias power supply 24 is connected between the bias electrode 19 and the plasma generation chamber 11. The bias power supply 24 in the first modification is configured to be able to switch the positive and negative of the output voltage supply.

The bias power supply 24 in the first modification may be, for example, a bipolar power supply. The bias power supply 24 in the first modification may be configured by combining one or more DC power supplies and switches, for example.

A controller 31 can be provided to control power output by the filament power supply 21, cathode power supply 22, bias power supply 24 and/or emitter power supply 23 in accordance with the principles and methods described herein with respect to the circuit.

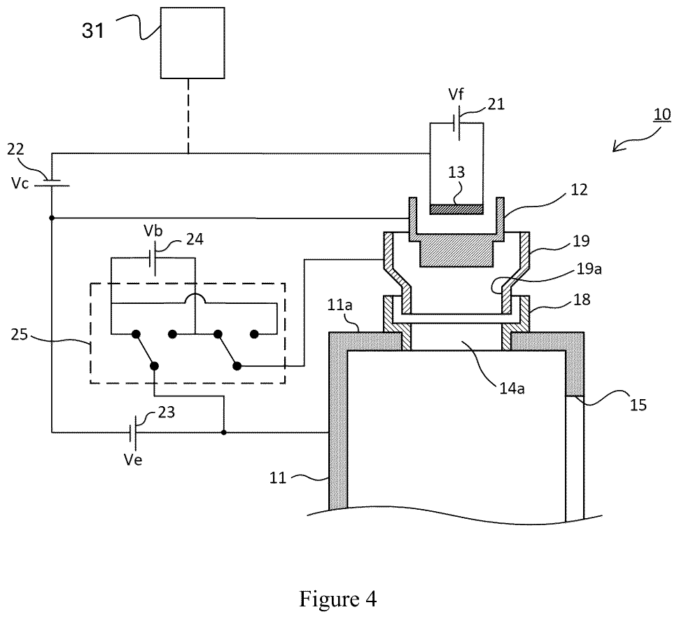

FIG. 4 is a diagram showing a cross section of the periphery of the cathode 12 in accordance with a second modification of the ion source 10 and a circuit configuration of the ion source 10. In FIG. 4, only one cathode 12 and the structure around the cathode 12 are shown, as in FIG. 2.

As shown in FIG. 4, in the second modification, a bias power supply 24 is disposed between the plasma generation chamber 11 and the bias electrode 19 via a switch 25 on the circuit. In this modification, by switching the switch 25, it is possible to switch whether the bias electrode 19 is set to a positive potential or a negative potential with respect to the plasma generation chamber 11.

In this embodiment, hereinafter, the potential of the bias electrode 19 with respect to the plasma generation chamber 11 may be simply referred to as “the potential of the bias electrode 19”. Further, setting the bias electrode 19 to a positive potential with respect to the plasma generation chamber 11 may be simply referred to as “setting the bias electrode 19 to a positive potential”, and setting the bias electrode 19 to a negative potential with respect to the plasma generation chamber 11 may be simply referred to as “setting the bias electrode 19 to a negative potential”.

Testing was conducted in which the potential of the bias electrode 19 was changed for a plurality of source gases, and the beam current of the ion beam IB extracted at each potential was measured.

In the conventional ion source, the anode can be set to either a positive potential with respect to the ionization chamber or the same potential as the ionization chamber. In contrast, testing was conducted which confirmed that there is an ion species in which the extraction efficiency of the ion beam IB is improved by setting the bias electrode 19 to a negative potential in the ion source 10, compared to the ion source of conventional systems.

A test was also conducted in which an ion implantation apparatus including the ion source 10 was used to generate an ion beam of monoatomic ions or an ion beam of molecular ions from a plurality of types of source gases, and a beam current value was measured. More specifically, a test was conducted in which, for the ion beam generated from each source gas, only the potential of the bias electrode 19 with respect to the plasma generation chamber 11 was sequentially changed under predetermined conditions, and the beam current value was measured.

The ion implantation apparatus can include a mass analysis magnet for performing mass analysis of the ion beam extracted from the ion source 10, and the test is performed by measuring a beam current of the ion beam including desired ions immediately after the mass analysis.

A controller 31 can be provided to control power output by the filament power supply 21, cathode power supply 22, bias power supply 24, emitter power supply 23, and/or switch 25 in accordance with the principles and methods described herein with respect to the circuit.

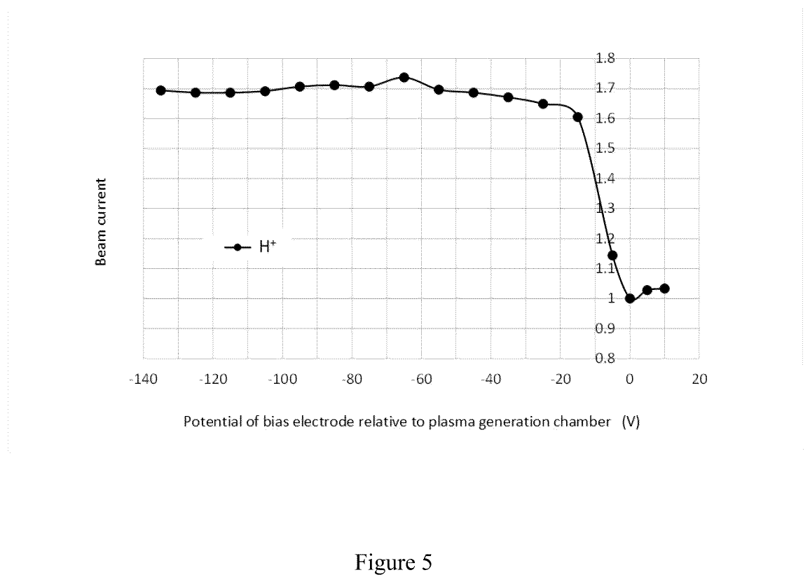

FIGS. 5 to 7 show the results of the tests described above, and show the relationship between the potential of the bias electrode 19 with respect to the plasma generation chamber 11 and the beam current value. In FIGS. 5 to 7, the measured beam current value is expressed as a ratio to the beam current value when the bias electrode 19 has the same potential as the plasma generation chamber 11. Thus, FIGS. 5 to 7 illustrate the relationship between the potential of the bias electrodes 19 and the beam current values when the beam current values measured when the potential of the bias electrodes 19 with respect to the plasma generation chamber 11 is at 0V are set to 1.

FIG. 5 shows the test results when hydrogen (H₂) gas was used as the source gas and an ion beam of monoatomic ions, that is, a hydrogen ion (H⁺) beam was extracted.

It is understood from FIG. 5 that, when an ion beam of monoatomic ions (hydrogen ion beam) is extracted from hydrogen gas, a higher beam current value tends to be obtained when the potential of the bias electrode 19 with respect to the plasma generation chamber 11 is set to a negative potential than when the potential is set to a positive potential. It is understood from FIG. 5 that the beam current has a maximum value when the potential of the bias electrodes 19 is −65V.

Thus, when the hydrogen ions are extracted using the ion source 10, the potential of the bias electrode 19 with respect to the plasma generation chamber 11 is set to be negative, so that the generation efficiency of the hydrogen ions in the plasma generation chamber 11 is improved and the extraction efficiency of the ion beam is improved as compared with the conventional systems. In particular, when the potential of the bias electrodes 19 is −65V, the production efficiency of the ion beam is maximized.

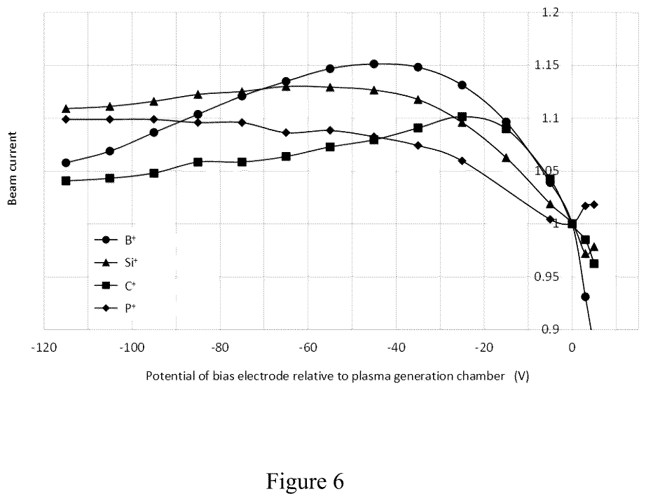

FIG. 6 shows the test results when BF₃ gas, SiF₄ gas, CO₂ gas, and PH₃ gas were used as the source gas, and an ion beam of monoatomic ions was extracted from each source gas. More particularly, the test results are obtained when a B⁺ ion beam, a Si⁺ ion beam, a C⁺ ion beam, and a P⁺ ion beam are extracted from a BF₃ gas, a SiF₄ gas, a CO₂ gas, and a PH₃ gas, respectively.

It is understood from FIG. 6 that, when the BF₃ gas, the SiF₄ gas, the CO₂ gas, or the PH₃ gas is used as the source gas and the ion beam of the monoatomic ions, that is, B⁺, Si⁺, C⁺, or P⁺ is extracted, a higher beam current tends to be obtained when the potential of the bias electrodes 19 with respect to the plasma generation chamber 11 is set to a negative potential than when the potential is set to a positive potential.

As can be understood from FIGS. 5 and 6, when an ion beam of H⁺, B⁺, Si⁺, C⁺, or P⁺, which is a monoatomic ion, is extracted, the potential of the bias electrode 19 with respect to the plasma generation chamber 11 is set to be negative, so that the generation efficiency of the monoatomic ion is improved and the extraction efficiency of the ion beam is improved as compared with conventional systems. The reason for this is presumed to be, for example, that the confinement of electrons in the cylindrical portion 19a of the bias electrodes 19 is improved, and the transport of electrons to the plasma generation chamber 11 is improved.

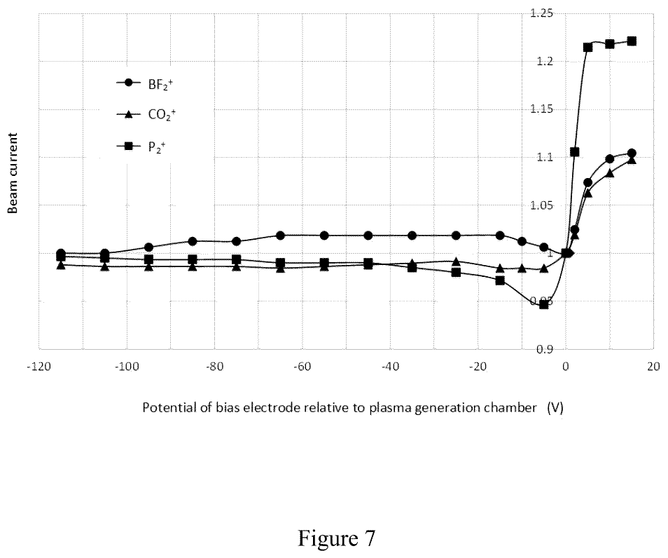

FIG. 7 shows the test results when the BF₃ gas, the CO₂ gas, and the PH₃ gas were used as the source gas, and the ion beam of the molecular ions was extracted from each source gas. To be more specific, the test results are obtained when an ion beam of BF3⁺, an ion beam of CO₂⁺, and an ion beam of PH₃⁺ are extracted from BF₂ gas, CO₂ gas, and P₂ gas, respectively.

It is understood from FIG. 7 that, in the case where the BF₃ gas, the CO₂ gas, or the PH₃ gas is used as the source gas and the ion beam of BF₂⁺, CO₂⁺, or P₂⁺ as the molecular ions is extracted, a higher beam current tends to be obtained when the potential of the bias electrodes 19 with respect to the plasma generation chamber 11 is set to a positive potential than when the potential is set to a negative potential.

In the ion source 10 of this embodiment, the bias electrode 19 can be set to a negative potential with respect to the plasma generation chamber 11, and the bias electrode 19 can also be set to a positive potential with respect to the plasma generation chamber 11. Therefore, the bias electrode 19 is set to a negative potential for an ion species for which a higher beam current value is obtained when the bias electrode 19 is set to a negative potential. Further, the bias electrode 19 is set to a positive potential for an ion species that provides a higher beam current value when the bias electrode 19 is set to a positive potential.

In particular, from the above test results, when the desired ion species is a monoatomic ion such as H⁺, B⁺, Si⁺, C⁺, and P⁺, H₂ gas, BF₃ gas, SiF₄ gas, CO₂ gas, PH₃ gas, and the like used as the source gas, the bias electrodes 19 can be set to a negative potential with respect to the plasma generation chamber 11. The ion source 10 set in this manner generates the ion beam IB having a higher beam current value than that of the conventional ion source. That is, the extraction efficiency of the ion beam is improved as compared with the conventional case.

In addition, when the desired ion species is a molecular ion, the ion source 10 may set the bias electrode 19 to a positive potential with respect to the plasma generation chamber 11 to generate the ion beam IB.

In the ion source 10, when the monoatomic ions are extracted, the extraction efficiency of the ion beam IB is not necessarily improved in a case where the bias electrode 19 is set to a negative potential rather than a case where the bias electrode 19 is set to a positive potential.

For example, the disclosed subject matter confirms that, in a case where an ion beam formed of relatively heavy (having a relatively large formula weight) monoatomic ions such as Ar⁺ is extracted, an ion beam having a higher beam current value can be generated in some cases by setting the bias electrode 19 to a positive potential.

When the ion source 10 of this embodiment is operated, whether the bias electrode 19 is operated at a negative potential or at a positive potential is determined depending on the desired ion species.

Thus, in the method of operating the ion source 10 in this embodiment, the ion source 10 is used, and whether the bias electrode 19 is set to a positive potential with respect to the plasma generation chamber 11 or the bias electrode 19 is set to a negative potential with respect to the plasma generation chamber 11 is selected according to a desired ion species.

As described above, when the desired ion species is a relatively light (relatively small formula weight) monoatomic ion such as H⁺, B⁺, Si⁺, N⁺, and Ne⁺, the bias electrode 19 is set to a negative potential with respect to the plasma generation chamber 11. Accordingly, compared to an instance where the bias electrode 19 is set to a positive potential, the ion beam IB having a higher beam current value can be generated, and the extraction efficiency of the ion beam IB is improved.

In addition, when the desired ion species is a relatively heavy (formula weight is relatively large) monoatomic ion, such as a molecular ion and an ion beam of Ar⁺, the bias electrode 19 is set to a positive potential.

It should be understood that embodiments are not limited to the various embodiments described above with reference to the drawings, but various other changes and modifications may be made therein without departing from the spirit and scope thereof as set forth in appended claims.

What is claimed is:

1. An ion source for generating an ion beam containing a predetermined ion species, comprising:
a cathode that emits electrons;
a plasma generation chamber having an opening region through which the electrons pass, and in which plasma containing the ion species is generated from a source gas; and
an electrode disposed between the cathode and the opening region, the electrode including a cylindrical portion through which the electrons pass,
wherein the electrode is configured to be set to a negative potential with respect to the plasma generation chamber.

2. The ion source of claim 1, wherein the electrode is configured to switch between the negative potential and a positive potential with respect to the plasma generation chamber.

3. The ion source of claim 2, further comprising:
a circuit configured to provide the electrode with at least one of the negative potential with respect to the plasma generation chamber and the positive potential with respect to the plasma generation chamber.

4. The ion source according to claim 3, wherein the circuit is configured to set the electrode to a negative potential with respect to the plasma generation chamber to generate the ion beam if the ion species is a monoatomic ion.

5. The ion source according to claim 3, wherein the circuit is configured to set the electrode to a positive potential with respect to the plasma generation chamber to generate the ion beam if the ion species is a molecular ion.

6. The ion source according to claim 3, wherein the electrode is a bias electrode and the circuit includes a bias power supply connected to the bias electrode and an emitter power supply connected to the plasma generation chamber, and the bias power supply is configured to provide a voltage that is less than an emitter voltage provided by the emitter power supply to the plasma generation chamber.

7. The ion source of claim 2, further comprising:
a controller configured to selectively provide the electrode with one of
the negative potential with respect to the plasma generation chamber, and
the positive potential with respect to the plasma generation chamber.

8. The ion source according to claim 7, wherein the controller is configured to set the electrode to a negative potential with respect to the plasma generation chamber to generate the ion beam if an input is received indicating that the ion species is a monoatomic ion.

9. The ion source according to claim 7, wherein the controller is configured to set the electrode to a positive potential with respect to the plasma generation chamber to generate the ion beam if an input is received indicating that the ion species is a molecular ion.

10. A method for operating an ion source that generates an ion beam containing a predetermined ion species, the ion source including a cathode that emits electrons, a plasma generation chamber having an opening region and an electrode disposed between the cathode and the opening region, the electrode including a tubular portion, the method comprising:
passing electrons through the opening region of the plasma generation chamber in which plasma containing the ion species is generated from a source gas;
passing electrons through the tubular portion of the electrode; and
selecting whether to set the electrode to a positive potential with respect to the plasma generation chamber or to set the electrode to a negative potential with respect to the plasma generation chamber, depending on the ion species.

11. The method of claim 10, further comprising:
providing a circuit configured to provide the electrode with at least one of the negative potential with respect to the plasma generation chamber and the positive potential with respect to the plasma generation chamber.

12. The method of claim 10, further comprising:
setting the electrode to a negative potential with respect to the plasma generation chamber to generate the ion beam if the ion species is a monoatomic ion.

13. The method of claim 10, further comprising:
setting the electrode to a positive potential with respect to the plasma generation chamber to generate the ion beam if the ion species is a molecular ion.

14. The method of claim 10, further comprising:
providing a circuit configured to provide the electrode with at least one of the negative potential with respect to the plasma generation chamber and the positive potential with respect to the plasma generation chamber, wherein the electrode is a bias electrode and the circuit includes a bias power supply connected to the bias electrode and an emitter power supply connected to the plasma generation chamber, and the method includes,
providing a bias voltage from the bias power supply to the bias electrode; and
providing an emitter voltage from the emitter power supply to the plasma generation chamber, wherein the bias voltage is less than the emitter voltage.

15. The method of claim 10, further comprising:
providing a controller;
providing the controller with information that the ion species is one of a monoatomic ion and a molecular ion;
causing the controller to set the electrode to a negative potential with respect to the plasma generation chamber if the ion species is a monoatomic ion; and
causing the controller to set the electrode to a positive potential with respect to the plasma generation chamber if the ion species is a molecular ion.

16. A method for operating an ion source that generates an ion beam containing a predetermined ion species, the method comprising:
providing a cathode that emits electrons, a plasma generation chamber having an opening region, and an electrode disposed between the cathode and the opening region;
passing electrons through the opening region of the plasma generation chamber in which plasma containing the ion species is generated from a source gas;
passing electrons through the electrode;
setting the electrode to a negative potential with respect to the plasma generation chamber if the ion species is a monoatomic ion.

17. The method of claim 16, further comprising:
setting the electrode to a positive potential with respect to the plasma generation chamber to generate the ion beam if the ion species is a molecular ion.

18. The method of claim 16, further comprising:
providing a circuit configured to provide the electrode with the negative potential with respect to the plasma generation chamber, wherein the electrode is cylindrical in shape; and
passing electrons includes passing electrons through the cylindrical shape of the electrode.

19. The method of claim 16, further comprising:
providing a circuit including a bias power supply connected to the electrode and an emitter power supply connected to the plasma generation chamber;
providing a bias voltage from the bias power supply to the electrode; and
providing an emitter voltage from the emitter power supply to the plasma generation chamber, wherein the bias voltage is less than the emitter voltage.

20. The method of claim 16, further comprising:
providing a controller;
providing the controller with information that the ion species is one of a monoatomic ion and a molecular ion;
causing the controller to set the electrode to a negative potential with respect to the plasma generation chamber if the ion species is a monoatomic ion.
